(19) United States
(12) Patent Application Publication
(10) Pub. No.: US 2026/0026300 A1
(43) Pub. Date: Jan. 22, 2026

(54) PURGE NOZZLE, SUBSTRATE PROCESSING APPARATUS, METHOD OF PURGING SUBSTRATE CONTAINER, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Takeshi ITO, Toyama-shi (JP); Tatsuya NISHINO, Toyama-shi (JP)

(73) Assignee: Kokusai Electric Corporation, Tokyo (JP)

(21) Appl. No.: 19/344,412

(22) Filed: Sep. 29, 2025

Related U.S. Application Data
(63) Continuation of application No. PCT/JP2023/034333, filed on Sep. 21, 2023.

(51) Int. Cl. H01L 21/673

(52) U.S. Cl. CPC H01L 21/67389

(57) ABSTRACT

There is provided a technique that includes: a close contact structure having an opening and capable of contacting a purge port of a substrate container; a bushing connected to a surface of the close contact structure opposite to its surface contacting the purge port, and provided with a cylinder communicating with the opening; a gas pipe clearance-fitted with an inner periphery of the cylinder along a first gap; a port flange fixedly connected to the gas pipe and provided with a surface perpendicular to an axis of the gas pipe; and an elastic structure between the port flange and the bushing to bias the bushing away from the port flange including a hole concentric with the gas pipe, a diameter of the hole corresponds to an outer diameter of the cylinder, and an outer periphery of the cylinder is clearance-fitted with the hole along a second gap.

### CROSS-REFERENCE TO RELATED PATENT APPLICATION

This application is a bypass continuation application of PCT International Application No. PCT/JP2023/034333, filed on Sep. 21, 2023, in the WIPO, the entire contents of which are hereby incorporated by reference.

### BACKGROUND

### 1. Field

The present disclosure relates to a purge nozzle, a substrate processing apparatus, a method of purging a substrate container, a method of manufacturing a semiconductor device and a non-transitory computer-readable recording medium.

### 2. Related Art

According to some related arts, in a semiconductor manufacturing apparatus, a substrate to be processed may be stored in a FOUP (Front Opening Unified Pod) serving as a substrate container and transferred to a mounting structure (which is a placement structure). A purge gas may be supplied to the FOUP in the semiconductor manufacturing apparatus.

The purge gas may be supplied to the FOUP by connecting a purge nozzle to a purge port at a bottom of the FOUP. However, it is preferable to improve contact characteristics with respect to the purge nozzle.

### SUMMARY

According to the present disclosure, there is provided a technique capable of improving contact characteristics with respect to a purge nozzle.

According to the embodiments of the present disclosure, there is provided a technique that includes: a close contact structure provided with an opening in a center portion thereof and configured to be capable of coming into close contact with a purge port of a substrate container; a bushing connected to a surface of the close contact structure opposite to a surface of the close contact structure in close contact with the purge port, and provided with a cylinder communicating with the opening; a gas pipe clearance-fitted with an inner periphery of the cylinder along a first gap; a port flange fixedly connected to the gas pipe and provided with a flange surface substantially perpendicular to a pipe axis of the gas pipe; and an elastic structure provided between the port flange and the bushing and configured to bias the bushing in a direction away from the port flange. The port flange is provided with a hole concentric with the gas pipe, a diameter of the hole corresponds to an outer diameter of the cylinder, and an outer periphery of the cylinder is clearance-fitted with the hole along a second gap.

### BRIEF DESCRIPTION OF THE DRAWINGS

FIG. 1 is a diagram schematically illustrating a perspective view of a storage chamber preferably used in one or more embodiments of the present disclosure.

FIG. 2 is a diagram schematically illustrating a vertical cross-section of a substrate processing apparatus preferably used in the embodiments of the present disclosure.

FIG. 3 is a diagram schematically illustrating a horizontal driving structure preferably used in the embodiments of the present disclosure, when viewed from above.

FIG. 4 is a diagram schematically illustrating the horizontal driving structure preferably used in the embodiments of the present disclosure, when viewed from behind.

FIG. 5 is a diagram schematically illustrating a configuration of a purge gas supplier preferably used in the embodiments of the present disclosure.

FIG. 6 is a diagram schematically illustrating a vertical cross-section of a purge nozzle preferably used in the embodiments of the present disclosure.

FIG. 7 is a diagram schematically illustrating a configuration of a controller of the substrate processing apparatus preferably used in the embodiments of the present disclosure.

FIG. 8 is a flow chart schematically illustrating a substrate processing applied in the embodiments of the present disclosure.

FIG. 9 is a diagram schematically illustrating a vertical cross-section of a purge nozzle according to a first modified example of the embodiments of the present disclosure.

FIG. 10 is a diagram schematically illustrating a vertical cross-section of a purge nozzle according to a second modified example of the embodiments of the present disclosure.

FIG. 11 is a diagram schematically illustrating a vertical cross-section of a purge nozzle according to a third modified example of the embodiments of the present disclosure.

### DETAILED DESCRIPTION

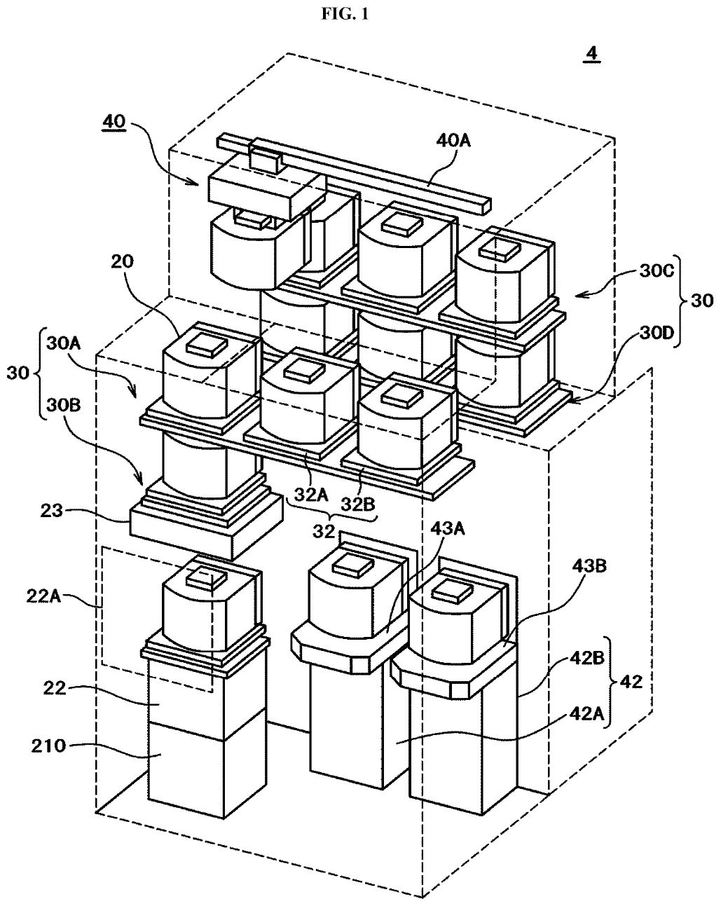

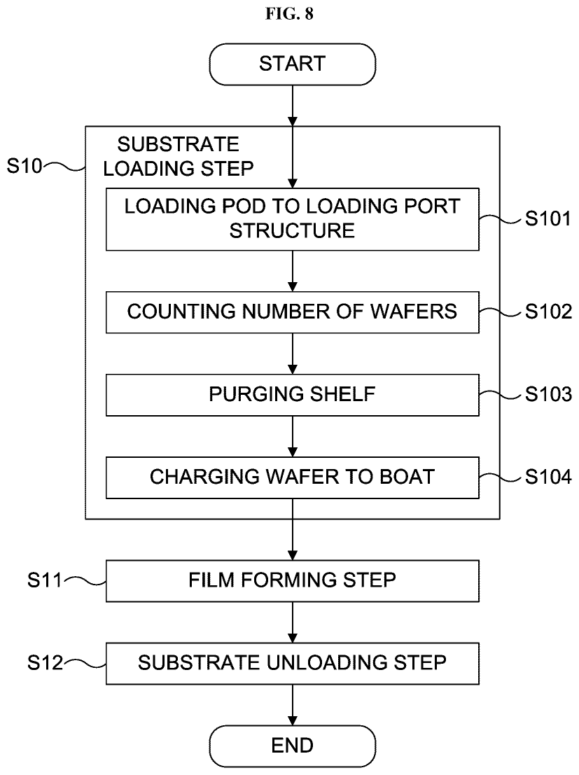

Hereinafter, one or more embodiments (hereinafter, also simply referred to as “embodiments”) according to the present disclosure will be described mainly with reference to FIGS. 1 to 8. For example, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match. In addition, the same or similar reference numerals represent the same or similar components in the drawings. Thus, each component is described with reference to the drawing in which it first appears, and redundant descriptions related thereto will be omitted unless particularly necessary. Further, the number of each component described in the present specification is not limited to one, and the number of each component may be two or more unless otherwise specified in the present specification.

### (1) Configuration of Substrate Processing Apparatus

As shown in FIG. 1, according to the present embodiments, a substrate processing apparatus 4 is configured as a vertical type processing apparatus (batch and vertical type processing apparatus) configured to perform processing steps in a method of manufacturing a semiconductor device. In addition, as the vertical type processing apparatus to which the technique of the present disclosure is applied, FOUPs (Front Opening Unified Pods) (hereinafter, also referred to as “pods”) 20 are used. Hereinafter, each of the pods 20 may also be referred to as a “pod 20”. The pod 20 serves as a carrier used when a plurality of wafers W serving as substrates are transferred. Hereinafter, each of the wafers W may also be referred to as a “wafer W” which serves as a substrate. The substrate processing apparatus 4 includes a process furnace 8, a storage chamber (also referred to as an “accommodation chamber”) 12, and a transfer chamber 16, which will be described later.

### <Storage Chamber>

At a front portion (front space) in a housing of the substrate processing apparatus 4, the storage chamber 12 (which the pod 20 is transferred (loaded) into and stored therein) of the substrate processing apparatus 4 is provided. At a front portion of a housing of the storage chamber 12, a loading/unloading port 22A (which serves as an opening through which the pod 20 is transferred (loaded) into or transferred (unloaded) out of the storage chamber 12) is provided so as to communicate between an inside (inner portion) and an outside (outer portion) of the housing of the storage chamber 12. The loading/unloading port 22A may be configured to be opened and closed by a front shutter (not shown). An AGV (Automated Guided Vehicle) port structure (also referred to as an “I/O stage”) 22 is provided inside the housing of the storage chamber 12 in a manner corresponding to the loading/unloading port 22A. A loading port structure 42 described later is installed on a wall between the storage chamber 12 and the transfer chamber 16. The pod 20 can be loaded into the substrate processing apparatus 4 via the AGV port structure 22 by an intra-process transfer apparatus (or an inter-process transfer apparatus) provided outside the substrate processing apparatus 4, and can also be unloaded from the AGV port structure 22.

At the front portion of the housing of the storage chamber 12 and above the AGV port structure 22, storage shelves (pod shelves) 30A and 30B capable of storing the pod 20 are installed in two stages in a vertical direction (that is, the storage shelf 30A is provided above the storage shelf 30B). In addition, at a rear portion of the housing of the storage chamber 12, storage shelves (pod shelves) 30C and 30D capable of storing the pod 20 are installed in two stages in the vertical direction (that is, the storage shelf 30C is provided above the storage shelf 30D). For example, each of the storage shelves 30C and 30D can store three pods 20. That is, it can also be said that each of the storage shelves 30C and 30D is provided with three shelves. The three shelves of the storage shelf 30C may also be referred to as “storage shelves 30C_1, 30C_2 and 30C_3”, respectively, and the three shelves of the storage shelf 30D may also be referred to as “storage shelves 30D_1, 30D_2 and 30D_3”, respectively. Unless the storage shelves 30A, 30B, 30C and 30D are described separately, the storage shelves 30A, 30B, 30C and 30D may also be collectively or individually referred to as “storage shelves 30” or a “storage shelf 30”.

OHT (Overhead Hoist Transfer) port structures 32A and 32B are installed side by side (laterally) on the same horizontal line as the upper storage shelf 30A at the front portion of the housing of the storage chamber 12. Unless the OHT port structures 32A and 32B are described separately, the OHT port structures 32A and 32B may also be collectively or individually referred to as “OHT port structures 32” or an “OHT port structure 32”. The pod 20 can be loaded into the substrate processing apparatus 4 and placed on the OHT port structure 32 from above the substrate processing apparatus 4 by the intra-process transfer apparatus (or the inter-process transfer apparatus) provided outside the substrate processing apparatus 4, and can also be unloaded from the OHT port structure 32. Each of the AGV port structure 22, the storage shelf 30 and the OHT port structure 32 is configured to allow the pod 20 to be moved horizontally between a placement position and a delivery position by a horizontal driving structure (also referred to as a “horizontal driver”) 26. The horizontal driving structure 26 will be described in detail later.

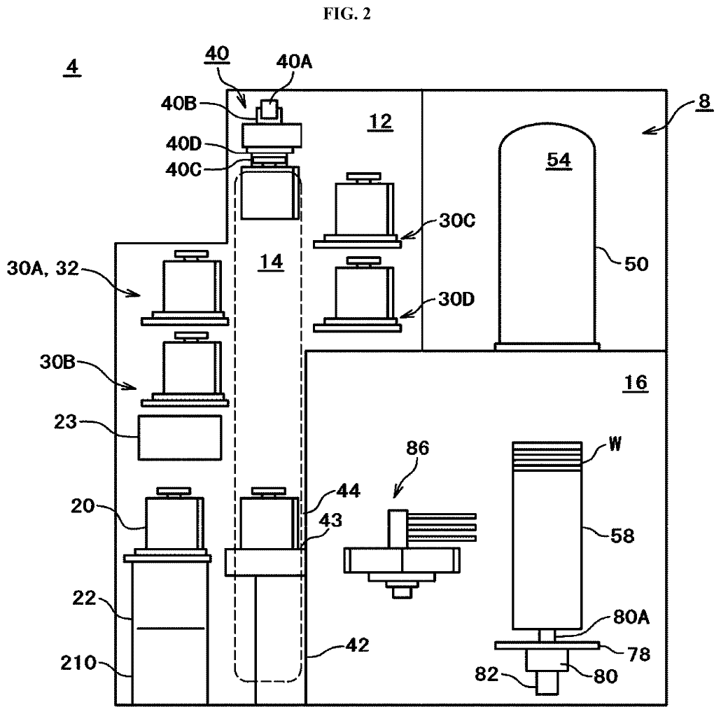

As shown in FIG. 2, a pod transfer area (pod transfer region) 14 is formed (defined) by a space within the housing of the storage chamber 12 between the storage shelves 30A and 30B (which are installed at the front portion of the housing) and the storage shelves 30C and 30D (which are installed at the rear portion of the housing). The pod 20 is delivered and transferred in the pod transfer area 14. A rail structure 40A is provided at a ceiling of the pod transfer area 14 (that is, a ceiling of the storage chamber 12). The rail structure 40A serves as a running path for a pod transfer structure 40 described later. In the present embodiments, the delivery position is located within the pod transfer area 14, for example, directly below the pod transfer structure 40.

The pod transfer structure 40 configured to transfer the pod 20 may include: a traveling structure 40B configured to run on the rail structure 40A; a holder (which is a holding structure) 40C configured to hold (or support) the pod 20; and an elevator (which is an elevating structure) 40D configured to elevate and lower the holder 40C in the vertical direction. By detecting an encoder of a motor configured to drive the traveling structure 40B, it is possible to detect a position of the traveling structure 40B, and it is also possible to move the traveling structure 40B to an appropriate position. For example, the pod transfer structure 40 is configured as a wire-suspended type transfer structure (hoist).

Above the pod 20 placed on the AGV port structure 22 and below the storage shelf 30B (which is provided below the storage shelf 30A), a purge gas supplier (which is a purge gas supply system) 23 is provided. The purge gas supplier 23 will be described in detail later.

### <Transfer Chamber>

The transfer chamber 16 is located adjacent to a rear portion of the storage chamber 12. On a side surface of the storage chamber 12 adjacent to the transfer chamber 16, a plurality of wafer loading/unloading ports 44 through which the wafer W is loaded into and unloaded out of the transfer chamber 16 are provided (opened) while arranged in a horizontal direction. Loading port structures 42A and 42B are installed for the wafer loading/unloading ports 44. Each of the loading port structures 42A and 42B is configured to move mounting tables (also referred to as “placement tables”) 43A and 43B capable of holding the pod 20 so as to press each of the mounting tables 43A and 43B against the wafer loading/unloading ports 44 such that a lid of the pod 20 can be unfolded (or opened). When the lid of the pod 20 is unfolded, a substrate transfer structure 86 transfers the wafer W into or out of the pod 20. Unless the loading port structure 42A and 42B are described separately, the loading port structure 42A and 42B may also be collectively or individually referred to as “loading port structures 42” or the “loading port structure 42”. Unless the mounting tables 43A and 43B are described separately, the mounting tables 43A and 43B may also be collectively or individually referred to as “mounting tables 43” or a “mounting table 43”.

### <Process Furnace>

The process furnace 8 is installed above the transfer chamber 16. The process furnace 8 is provided with a reaction tube 50 constituting a reaction vessel (process vessel). For example, the reaction tube 50 is made of a heat resistant material such as quartz (SiO₂) and silicon carbide (SiC), and is of a cylindrical shape with a closed upper end and an open lower end. A process chamber 54 is formed in a hollow cylindrical portion of the reaction tube 50. The process chamber 54 is configured to be capable accommodating a boat 58 (which will be described later) configured to hold (or support) the wafers W in the vertical direction while the wafers W are horizontally oriented with their centers aligned with one another vertically in a multistage manner.

A seal cap 78 serving as a furnace opening lid capable of airtightly closing (or sealing) a lower end opening of the reaction tube 50 is provided below the reaction tube 50. For example, the seal cap 78 is made of a metal material such as SUS and stainless steel, and is of a disk shape. The seal cap 78 is configured to be in contact with (that is, abut against) the lower end of the reaction tube 50 from thereunder in the vertical direction.

The boat 58 serving as a substrate support is configured to accommodate (or support) the wafers W (for example, 25 wafers to 200 wafers) while the wafers W are horizontally oriented with their centers aligned with one another in the multistage manner, that is, with a predetermined interval therebetween in the vertical direction. For example, the boat 58 is made of a heat resistant material such as quartz and SiC.

A rotator (which is a rotating structure) 80 configured to rotate the boat 58 is provided at the seal cap 78 in a manner opposite to the process chamber 54. A rotating shaft 80A of the rotator 80 is connected to the boat 58 through the seal cap 78. The rotator 80 is configured to rotate the wafers W by rotating the boat 58.

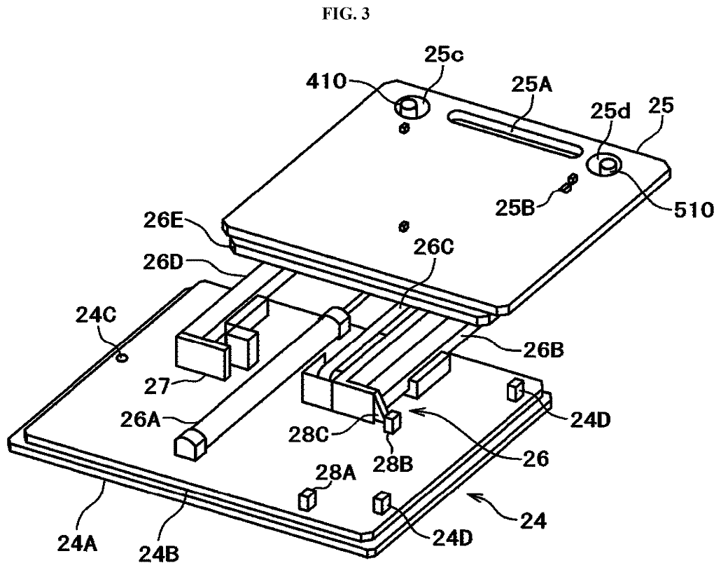

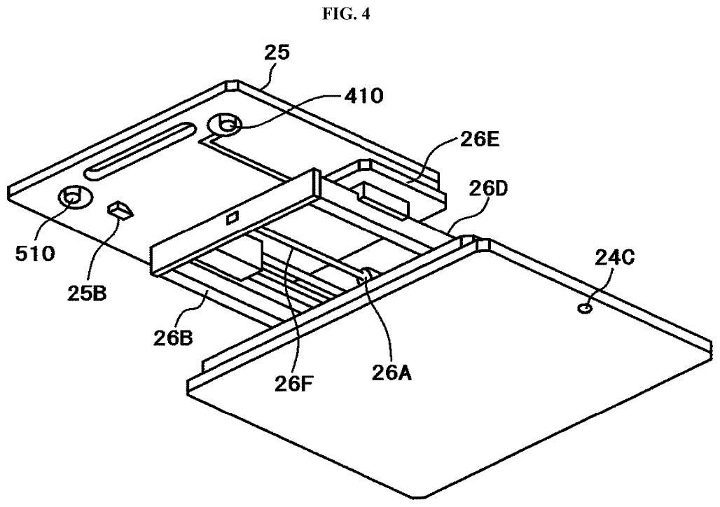

Subsequently, the horizontal driving structure 26 of the storage shelf 30, the AGV port structure 22 and the OHT port structure 32 according to the present embodiments will be described with reference to FIGS. 3 and 4. As shown in FIG. 3, the horizontal driving structure 26 is installed on a base (which is a base structure) 24, and is configured to horizontally move a stage 25 serving as a mounting structure (which is a mounting plate) on which the pod 20 is placed. As a result, it is possible to locate the stage 25 within the pod transfer area 14, and it is also possible to place the pod 20 on the stage 25 by the pod transfer structure 40.

The base 24 is constituted by a fixing plate 24A, an adjusting plate 24B, a fixing screw 24C and adjusting screws 24D. The fixing plate 24A and the adjusting plate 24B are connected by a plurality of adjusters. Each of the adjusters may be constituted by: the fixing screw 24C serving as a fastening structure capable of securing the fixing plate 24A and the adjusting plate 24B; and the two adjusting screws 24D serving as horizontal adjusting structures installed opposite to the fixing screw 24C. It is possible to adjust the horizontality of the stage 25 by adjusting a tightness of the adjusting screws 24D.

As shown in FIG. 3, the horizontal driving structure 26 is constituted by a first driver 26A, a pair of guide structures 26B and 26D, a transmission structure (belt) 26C, a pulley (not shown), a connecting structure (connecting plate) 26E, a first fixing structure (not shown) and a second fixing structure (not shown). The first driver 26A serves as a driver (driving structure) configured to move the stage 25 horizontally. The guide structures 26B and 26D are configured to move the stage 25 in parallel. The transmission structure 26C is configured to transmit a driving power of the first driver 26A. The pulley is installed inside one of the pairs of the guide structures 26B and 26C, for example, the guide structure 26B, and serves as a rotating structure configured to rotate the transmission structure 26C. The connecting structure 26E is of a flat shape, and is connected to a bottom of the stage 25. The first fixing structure is configured to secure the connecting structure 26E to the transmission structure 26C. The second fixing structure is configured to secure the transmission structure 26C to the adjusting plate 24B. For example, the first driver 26A is configured as an air cylinder or a motor. As shown in FIG. 4, front ends (tips) of the guide structures 26B and 26D are connected to each other to form a U-shape when viewed from above. The first driver 26A is installed substantially at a center between the guide structures 26B and 26D, and is configured to press a connecting portion that connects the guide structures 26B and 26D with a rod 26F.

The transmission structure 26C is configured as an endless belt-shaped structure, and is hung over the pulley. The transmission structure 26C and the connecting structure 26E are fixed by the second fixing structure of a block shape, and the transmission structure 26C and the adjusting plate 24B are fixed by a third fixing structure (not shown) of a block shape. Since the third fixing structure is fixed to the adjusting plate 24B, it is possible to rotate the transmission structure 26C when the guide structure 26B moves. By rotating the transmission structure 26C, it is possible to horizontally move the stage 25 fixed to the connecting structure 26E. With such a configuration, it is possible to simultaneously perform two horizontal movement operations, that is, a horizontal movement operation of the stage 25 by the guide structure 26B and a horizontal movement operation of the stage 25 by the transmission structure 26C. In addition, since the stage 25 can be moved horizontally in two stages, it is possible to save a space without lengthening the rod 26F of the first driver 26A.

Two sensors 28A and 28B are installed outside of the guide structure 26B on the adjusting plate 24B. For example, each of the sensors 28A and 28B is configured as a photosensor. The two sensors 28A and 28B are installed to detect the placement position and the delivery position of the stage 25, respectively. A detection structure 28C of a thin plate shape, which is used for a detection operation by the sensor 28B, is attached to a rear end of the guide structure 26B in the vicinity of where the sensor 28B is installed. A position of the stage 25 is detected when the detection structure 28C passes through a detection portion of the sensor 28B. By adjusting an installation position of the sensor 28B, it is possible to drive the stage 25 at any (appropriate) stroke. Thereby, it is possible to improve the controllability. A stopper 27 is attached to a rear end of the guide structure 26D to be located opposite to where the detection structure 28C is attached.

A sensor 25B is installed on the stage 25 to detect whether or not the pod 20 is placed on the stage 25. For example, the sensor 25B is configured as a photosensor. When the pod 20 is placed, a pin is pressed by a bottom surface of the pod 20, and the pin pressed as described above passes through a detection portion of the sensor 25B. Thereby, it is possible to detect that the pod 20 is placed on the stage 25. In addition, an opening 25A is provided (formed) at a front end (tip) of the stage 25. It is possible to use the opening 25A as a handle to transfer the stage 25 during a maintenance operation. With such a configuration, it is possible to improve the maintainability.

At the front portion of the housing, the storage shelf 30A (which is provided above the storage shelf 30B) and the OHT port structures 32A and 32B are installed on a single elongated base 24 such that the storage shelf 30A and the OHT port structures 32A and 32B can be driven independently. In addition, at the rear portion of the housing, the storage shelves 30C and 30D are installed on another single elongated base 24 such that the storage shelves 30C and 30D can be driven independently. On each of the elongated bases 24, three stages 25 are installed such that the three stages 25 can be driven independently.

Each of the storage shelf 30 and the OHT port structure 32 is provided with a purge structure configured to purge an atmosphere (inner atmosphere) of the pod 20 to reduce an oxygen concentration within the pod 20. The purge structure may also be provided in the AGV port structure 22.

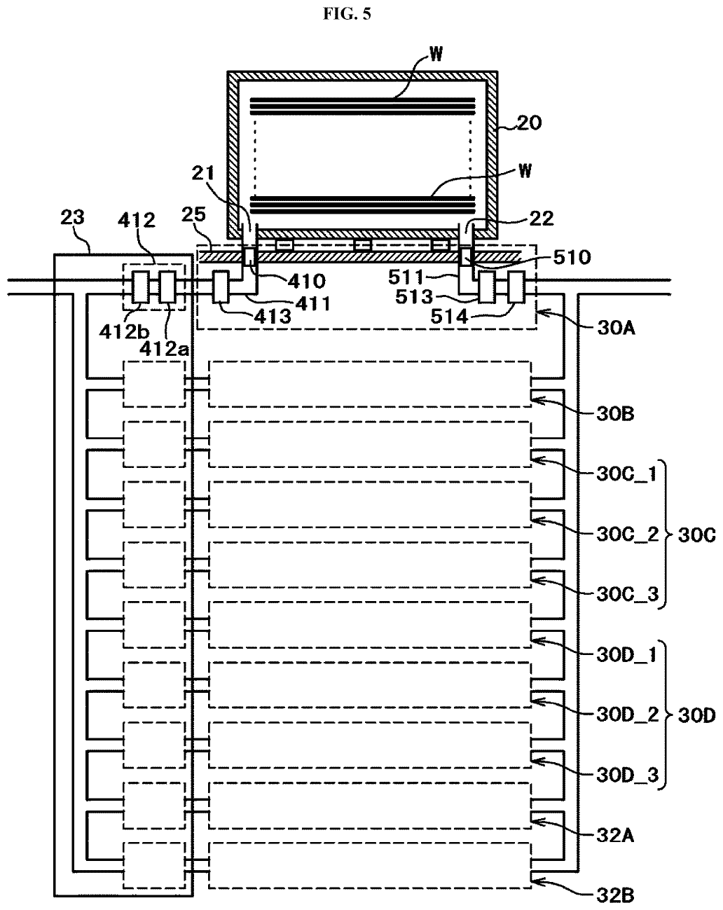

The purge structure will be described with reference to FIG. 5. The storage shelves 30A, 30B, 30C_1 to 30C_3 and 30D_1 to 30D_3 and the OHT port structures 32A and 32B are respectively provided with the stage 25. The stage 25 is provided with a purge nozzle 410 capable of being connected to a purge port 21 of the pod 20 and an exhaust nozzle 510 capable of being connected to the purge port 21. A gas supply pipe 411 is connected to the purge nozzle 410. The gas supply pipe 411 is provided with a gas filter 413 and a flow rate controller 412. The flow rate controller 412 is configured such that a flow rate related thereto is controlled by a controller 210 described below. The flow rate controller 412 is constituted by a valve 412a and a mass flow controller (MFC) 412b. A gas exhaust pipe 511 is connected to the exhaust nozzle 510. A pressure sensor 513 and a safety valve (relief valve) 514 are connected to the gas exhaust pipe 511.

The gas filter 413 connected to the gas supply pipe 411 and the pressure sensor 513 and the safety valve 514 connected to the gas exhaust pipe 511 are provided at each stage 25. In addition, the flow rate controller 412 connected to the gas supply pipe 411 is integrated into the purge gas supplier 23 at the front portion of the housing. As a result, it is possible to facilitate a manipulation, and it is also possible to improve the maintenance workability. The purge gas supplier 23 is configured as an integrated gas supplier (integrated gas supply system) which is connected to at least one of a plurality of purge nozzles 410 and configured to supply a gas. In addition, the controller 210 is configured to receive information on a type of the pod 20 inserted as described above from a host apparatus (not shown) and configured to control the integrated gas supplier to supply the gas through the purge port 21 corresponding to the type of the pod 20 placed on the stage 25.

When the pod 20 is placed on the stage 25 of one of the storage shelves 30A, 30B, 30C and 30D or one of the OHT port structure 32A and 32B, the sensor 25B mounted on the stage 25 detects that the pod 20 has been placed. When the controller 210 receives a signal from the sensor 25B, the controller 210 opens the valve 412a in the purge gas supplier 23 according to the signal. As a result, a purge gas is supplied to the pod 20 from a gas source (not shown) via the gas filter 413, the gas supply pipe 411, and the purge nozzle 410, and is exhausted (discharged) through the exhaust nozzle 510 via the gas exhaust pipe 511. As the purge gas, an inert gas is used. As the inert gas, for example, a gas such as nitrogen (N₂) gas may be used.

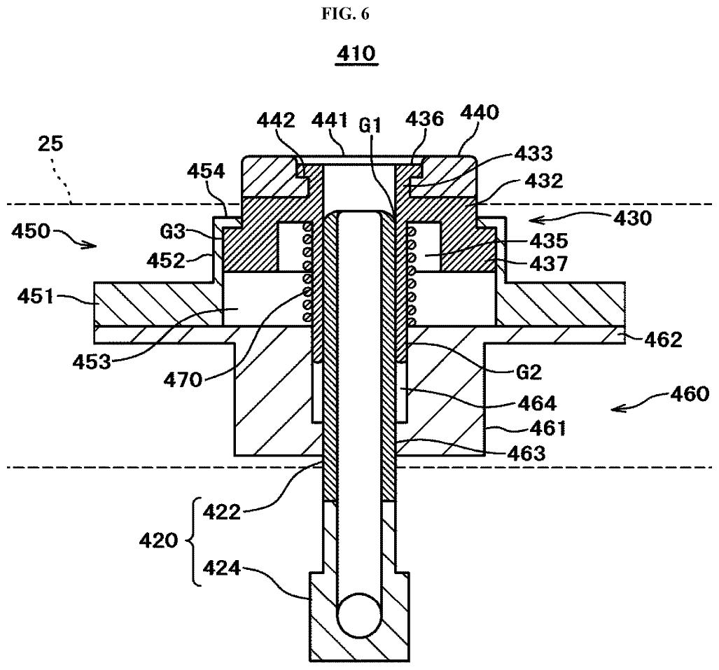

A configuration of the purge nozzle 410 will be described with reference to FIG. 6. The purge nozzle 410 is installed in a mounting hole (also referred to as an “installation hole”) 25C (see FIG. 3) that penetrates the stage 25 in an up-down direction (vertical direction). The purge nozzle 410 includes a piping structure 420, a bushing 430, a packing 440 serving as a close contact structure, a ring 450, a port flange 460 and a spring 470 serving as an elastic structure.

The piping structure 420 includes: a gas pipe 422 of a cylindrical shape provided with a flow path; and a coupler (which is a coupling structure) 424 provided with a flow path continuous with the flow path of the gas pipe 422. The gas pipe 422 is inserted through the bushing 430. The coupler 424 is provided below the stage 25 and connected to the gas supply pipe 411. As a result, the flow path of the piping structure 420 and the flow path of the gas supply pipe 411 are connected continuously, and the purge gas can flow through the piping structure 420. The piping structure 420 is fixed to the stage 25 by fixing the gas supply pipe 411 to a back surface of the stage 25 using a fixing structure and the like. A tip (upper end) of the gas pipe 422 is located at a position where the tip of the gas pipe 422 does not protrude above an upper surface of the stage 25. For example, the gas supply pipe 411 is configured as a SUS piping or a PTFE (Polytetrafluoroethylene) tube. In addition, for example, the piping structure 420 may be configured as a part of the gas supply pipe 411.

The bushing 430 includes a main body structure 432. A cylinder (which is a tubular structure or a plunger) 433 with a cylindrical through-hole (or bore) is provided inside the main body structure 432. The gas pipe 422 of the piping structure 420 is inserted into the through-hole of the cylinder 433. With the gas pipe 422 inserted into the cylinder 433, the bushing 430 is configured to be capable of being moved in the up-down direction along the gas pipe 422. A first gap G1 is defined between an inner surface of the cylinder 433 and an outer surface of the gas pipe 422. In other words, the gas pipe 422 is clearance-fitted against an inner periphery of the cylinder 433, along the first gap G1. A sliding surface of the cylinder 433, which slides against the gas pipe 422, is made of a resin, and is of a smooth cylindrical shape. By a low sliding resistance of such a resin, the bushing 430 is configured to be capable of being moved up and down smoothly. A length of the sliding surface in a sliding direction thereof is 1.5 times or more a diameter of the gas pipe 422. As a result, it is possible to reduce a conductance of the first gap G1. One end (upper end) of the gas pipe 422 is within the cylinder 433, and is located at a position such that the upper end of the gas pipe 422 does not protrude from the bushing 430 when the bushing 430 is pressed in by an external force. In addition, no seal ring is provided between the cylinder 433 and the gas pipe 422.

A groove (recess) 435 of a ring shape is provided on a lower surface of the main body structure 432 so as to surround the cylinder 433 when viewed from the up-down direction (that is, when viewed from above and below). An upper portion of the spring 470 is located in the groove 435. A flange (which is an edge) 436 protruding outward is provided at an upper end portion of the cylinder 433. In other words, the cylinder 433 extends through an opening 441 of the packing 440, and is provided with the flange 436 at a front end (tip) thereof. The through-hole of the cylinder 433 communicates with the opening 441. The packing 440 is installed between a lower surface of the flange 436 and an upper surface of the main body structure 432. In other words, the packing 440 is fixed by fitting a stepped structure 442 into the flange 436. A flange 437 protruding outward is provided at a lower end portion of the main body structure 432. An outer diameter of the flange 437 is set to be smaller than an inner diameter of the ring 450 described below. Thereby, a third gap G3 is defined.

The packing 440 is of an annular shape so as to surround the cylinder 433 when viewed from the up-down direction. A thickness of the packing 440 in an axial direction is set to be smaller than a difference between outer and inner diameters thereof. The packing 440 is provided with the opening 441 in a center thereof, and the stepped structure 442 is provided on a side surface of the opening 441. The packing 440 is fixed to the main body structure 432 by fitting the stepped structure 442 (which is provided at a lower end portion of an inner surface of the packing 440) into the flange 436. A surface (lower surface) of the packing 440, which is opposite to the packing's surface coming into close contact with the purge port 21, is connected to the cylinder 433. An upper surface of the packing 440 comes into close contact with the purge port 21 (see FIG. 5) provided on the bottom surface of the pod 20 when the pod 20 is placed on the stage 25. As a result, it is possible to communicate between the gas pipe 422 and the pod 20 via an area inside the packing 440 and the main body structure 432, and it is also possible to supply the purge gas into the pod 20.

Since the packing 440 repeatedly comes into contact with the pod 20, it is preferable that the packing 440 is highly durable. It is also preferable that the packing 440 does not easily adhere to the purge port 21 of the pod 20. In addition, to maintain the cleanliness of an inside (inner portion) of the pod 20, it is preferable that a generation amount of an outgas is small. Therefore, the packing 440 is made of a rubber or a resin capable of satisfying requirements mentioned above. In the present embodiments, the packing 440 is made of a fluororubber.

The ring 450 includes a main body structure 451 and a cylinder (which is a tubular structure) 452. The main body structure 451 is a fixing structure of an annular shape with a through-hole 453 in a center thereof. The cylinder 452 extends upward from an upper end portion of an inner surface of the main body structure 451, and is provided with the through-hole 453 in a center thereof. A restricting structure 454 extending inward is provided at an upper end portion of the cylinder 452. The bushing 430 is provided in the through-hole 453.

The port flange 460 includes a main body structure 461 and a flange 462. The main body structure 461 is a fixing structure of an annular shape with a through-hole 463 in a center thereof. The gas pipe 422 is inserted into the through-hole 463 and fixed by a method such as welding. In other words, the port flange 460 is fixedly connected to the gas pipe 422. The flange 462 is provided with a flange surface which is substantially perpendicular to a pipe axis of the gas pipe 422. The main body structure 461 is provided with a hole 464 concentric with the gas pipe 422, and a diameter of the hole 464 corresponds to an outer diameter of the cylinder 433. The outer periphery of the cylinder 433 is clearance-fitted into the hole 464, along a second gap G2.

The flange 437 of the bushing 430 is provided between the ring 450 and the port flange 460. As a result, a position of the bushing 430 in the up-down direction is restricted between an upper position where the flange 437 abuts against (that is, comes into contact with) a lower surface of the restricting structure 454 of the ring 450 and a lower position where the flange 437 abuts against an upper surface of the port flange 460. In other words, the ring 450 is fixed to a flange surface of the port flange 460, and the restricting structure 454 restricts the bushing 430 from moving away more than a predetermined distance from the port flange 460. In addition, the ring 450 is fixed to the flange surface of the port flange 460 with a screw inserted from a lower surface of the flange surface. The bushing 430 is located at the upper position when the pod 20 is not placed on the stage 25, and is located between the upper and lower positions when the pod 20 is placed on the stage 25. In other words, it is possible to press (push) the packing 440 to a position where the packing 440 does not protrude from the upper surface of the stage 25. In addition, it is also possible to press the gas pipe 422 to a position where the gas pipe 422 does not protrude from the upper surface of the stage 25. As a result, even when a sealing surface of the purge port 21 is flush with the upper surface of the stage 25, it is possible to place the pod 20 such that the pod 20 comes into close contact (that is, tightly fits) to the purge nozzle 410.

A side surface of the bushing 430 is clearance-fitted against an inner peripheral surface of the ring 450, along the third gap G3. Since the first gap G1, the second gap G2 and the third gap G3 are provided, it is possible to slide the bushing 430. In addition, the third gap G3 is located outside the first gap G1 and the second gap G2. For example, a diameter of the third gap G3 is about four times larger than a diameter of the first gap G1 and a diameter of the second gap G2. For example, when gap sizes of the first gap G1, the second gap G2 and the third gap G3 are the same, a flow path cross-sectional area of the third gap G3 is larger than a sum of flow path cross-sectional areas of the first gap G1 and the second gap G2. In other words, a conductance of the third gap G3 is set to be larger than a combined conductance of the first gap G1 and the second gap G2. As a result, when the bushing 430 is pressed in, the gas trapped beneath the bushing 430 is released (discharged) through the third gap G3. Thereby, it is possible to easily slide the bushing 430. In addition, when the bushing 430 slides through the second gap G2 or the third gap G3 rather than the first gap G1, the first gap G1 is set to be larger than the second gap G2 and the third gap G3.

The cylinder 433 is inserted into an inner area (inner region) of the spring 470. An upper end portion of the spring 470 is located in the groove 435 of the bushing 430. A lower end portion of the spring 470 abuts against the port flange 460. The spring 470 is compressed by the bushing 430 and the port flange 460. As a result, the spring 470 biases the bushing 430 toward the pod 20 (upward) in the up-down direction. In other words, the spring 470 biases the bushing 430 in a direction away from the port flange 460.

The exhaust nozzle 510 includes a configuration similar to that of the purge nozzle 410. The exhaust nozzle 510 is connected to the gas exhaust pipe 511 instead of the gas supply pipe 411, and the purge gas is exhausted from the pod 20 through the exhaust nozzle 510. The gas exhaust pipe 511 is configured as a tube piping.

An action (operation) when the pod 20 is placed on the stage 25 will be described. When the pod 20 approaches the stage 25, the packing 440 of the purge nozzle 410 first comes into contact with the purge port 21 of the pod 20. More specifically, the packing 440 comes into contact with a periphery of an opening constituting the purge port 21. Then, while a biasing force of the spring 470 keeps the purge port 21 and the packing 440 in close contact with each other, the packing 440 is pressed down by the pod 20. As the pod 20 approaches the stage 25 further, the pod 20 is placed on the stage 25 with the purge port 21 and the packing 440 in close contact (tight contact) with each other. In a manner described above, the spring 470 functions as a position adjusting structure capable of adjusting a position of the packing 440 in the up-down direction.

For example, a positional relationship between the purge port 21 and the purge nozzle 410 may change depending on the type of the pod 20. For example, a height of the sealing surface of the purge port 21 may vary within several millimeters depending on a manufacturer of the pod 20. Even in such a case, as long as the purge port 21 of the pod 20 and the packing 440 are in contact with each other, the biasing force of the spring 470 can keep the purge port 21 and the packing 440 in close contact with each other. Then, by pressing down the packing 440 by the pod 20, the position of the packing 440 in the up-down direction is automatically adjusted. As a result, even when the positional relationship between the purge port 21 of the pod 20 and the purge nozzle 410 changes, it is possible to reliably supply the purge gas into the pod 20.

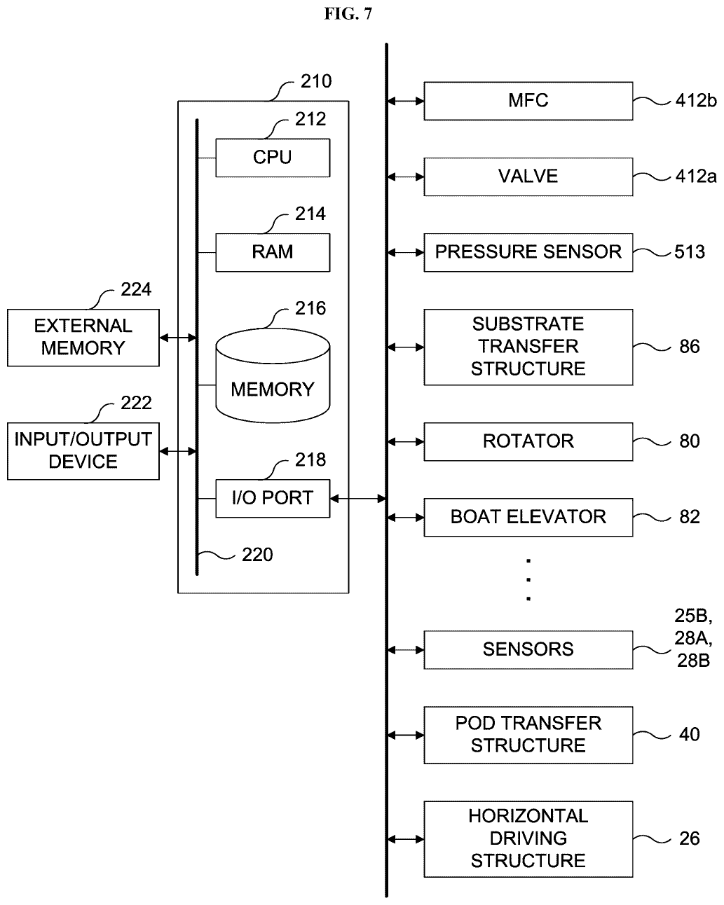

As shown in FIG. 7, the controller 210 is constituted by a computer including a CPU (Central Processing Unit) 212, a RAM (Random Access Memory) 214, a memory 216 and an I/O port (input/output port) 218. The RAM 214, the memory 216 and the I/O port 218 are configured to be capable of exchanging data with the CPU 212 through an internal bus 220. For example, an input/output device 222 (which is constituted by components such as a touch panel) is connected to the controller 210.

For example, the memory 216 is configured by a component such as a flash memory and a hard disk drive (HDD). For example, a control program configured to control an operation of the substrate processing apparatus 4 and a process recipe containing information on procedures and conditions of a substrate processing described later may be readably stored in the memory 216. The process recipe is obtained by combining steps (procedures) of the substrate processing described later such that the controller 210 can execute the steps by the substrate processing apparatus 4 to acquire a predetermined result, and functions as a program. Hereinafter, the process recipe and the control program may be collectively or individually referred to as a “program”. Thus, in the present specification, the term “program” may refer to the process recipe alone, may refer to the control program alone or may refer to both of the process recipe and the control program. The RAM 214 functions as a memory area where a program or data read by the CPU 212 is temporarily stored.

The I/O port 218 is connected to the components described above such as the MFC 412b, the valve 412a, the pressure sensor 513, the substrate transfer structure 86, the rotator 80, a boat elevator 82, the pod transfer structure 40, the sensors 25B, 28A and 28B and the horizontal driving structure 26.

The CPU 212 is configured to read the control program from the memory 216 and execute the control program read from the memory 216. In addition, the CPU 212 is configured to read the process recipe from the memory 216, for example, in accordance with an operation command inputted from the input/output device 222. In accordance with contents of the process recipe read from the memory 216, the CPU 212 may be configured to be capable of controlling various operations such as a wafer transfer operation by the substrate transfer structure 86, an operation of adjusting a rotation and a rotation speed of the boat 58 by the rotator 80, an elevating and lowering operation of the boat 58 by the boat elevator 82, a pod transfer operation by the pod transfer structure 40, and a driving operation of the horizontal driving structure 26 based on the sensors 25B, 28A and 28B. In addition, in accordance with the contents of the process recipe, the CPU 212 may be configured to be capable of controlling various operations such as a flow rate adjusting operation for the purge gas by the MFC 412b based on the pressure sensor 513 and an opening and closing operation of the valve 412a based on the sensor 25B.

The controller 210 may be embodied by installing the above-described program stored in an external memory 224 into the computer. For example, the external memory 224 may include a magnetic tape, a magnetic disk such as a flexible disk and a hard disk, an optical disk such as a CD and a DVD, a magneto-optical disk such as an MO and a semiconductor memory such as a USB memory and a memory card. The memory 216 or the external memory 224 may be embodied by a non-transitory computer readable recording medium. Hereafter, the memory 216 and the external memory 224 may be collectively or individually referred to as a “recording medium”. Thus, in the present specification, the term “recording medium” may refer to the memory 216 alone, may refer to the external memory 224 alone, or may refer to both of the memory 216 and the external memory 224. Instead of the external memory 224, a communication interface such as the Internet and a dedicated line may be used for providing the program to the computer.

### (2) Substrate Processing

Hereinafter, the substrate processing of processing the substrate using the substrate processing apparatus 4 will be described. For example, the substrate processing apparatus 4 serves as a semiconductor device manufacturing apparatus and the substrate processing serves as a part of a manufacturing process of a semiconductor device. In the following descriptions, operations of components constituting the substrate processing apparatus 4 are controlled by the controller 210.

### <Substrate Loading Step: S10>

As a substrate loading step S10, steps S101 to S104 are performed.

### <Loading Pod to Loading Port Structure: S101>

As shown in FIGS. 1 and 2, when the pod 20 is supplied to the AGV port structure 22 or the OHT port structure 32, the pod 20 on the AGV port structure 22 or the OHT port structure 32 is transferred by the pod transfer structure 40 to the mounting table 43 of the loading port structure 42.

### <Counting Number of Wafers: S102>

The wafer loading/unloading port 44 of the loading port structure 42 is closed by a cap attaching/detaching structure, and clean air is circulated and filled within the transfer chamber 16.

When an end surface of the pod 20 placed on the mounting table 43 of the loading port structure 42 is pressed against an opening edge of the wafer loading/unloading port 44, the cap attaching/detaching structure detaches a cap (that is, the lid) of the pod 20, and a wafer entrance of the pod 20 is opened. Then, a wafer counter counts the number of the wafers W in the pod 20 or checks states of the wafers W. After the number of the wafers W is counted, the cap is closed by the cap attaching/detaching structure.

### <Purging Shelf: S103>

The pod 20 is then transferred to and placed on the storage shelf 30. The pod 20 placed on the storage shelf 30 is purged. A purge may be performed continuously while the pod 20 is placed on the storage shelf 30, or may be performed intermittently at an appropriate time interval. In addition, a transfer step of transferring the pod 20 from the AGV port structure 22 or the OHT port structure 32 to the storage shelf 30 may be repeatedly performed as many times as the number of pods that can be placed on the storage shelf 30.

### <Charging Wafer to Boat: S104>

Among the pods 20 placed on the storage shelf 30, the pod 20 to be subjected to a film formation is transferred from the storage shelf 30 to the loading port structure 42 and placed on the mounting table 43 of the loading port structure 42. When the end surface of the pod 20 placed on the mounting table 43 is pressed against the opening edge of the wafer loading/unloading port 44, the cap attaching/detaching structure detaches the cap of the pod 20, and the wafer entrance of the pod 20 is opened. When the pod 20 is opened, the wafer W is then picked up from the pod 20 by the substrate transfer structure 86, and aligned in a circumferential direction by a notch aligner (which is a notch alignment device). Then, by the substrate transfer structure 86, the wafer W is charged (or transferred) into the boat 58. After loading the wafer W into the boat 58, the substrate transfer structure 86 returns to the pod 20 and charges a subsequent wafer W into the boat 58.

While the substrate transfer structure 86 charges the wafer W into the boat 58 from one of the loading port structures 42 (that is, one of the loading port structure 42A and the loading port structure 42B), another pod 20 is transferred from the storage shelf 30 onto the mounting table 43 of the other one of the loading port structures 42 (that is, the other one of the loading port structure 42A and the loading port structure 42B) by the pod transfer structure 40. Then, simultaneously with a charging operation (loading operation) for the wafer W, an opening operation for the pod 20 is performed by the loading port structure 42. After the wafers W are charged, the pod 20 (which is empty) is transferred from the loading port structure 42 to the storage shelf 30 and placed on the storage shelf 30. The pod 20 (which is empty) placed on the storage shelf 30 may be purged in a manner described above. In such a manner, the wafers W are charged (loaded) into the boat 58.

When a predetermined number of the wafers W are charged into the boat 58, a lower end portion of the process chamber 54 is opened. Subsequently, the seal cap 78 is elevated by the boat elevator 82 (see FIG. 2), and the boat 58 holding the wafers W is loaded into the process chamber 54 (boat loading).

### <Film Forming Step: S11>

Subsequently, by supplying a process gas to the wafer W in the process chamber 54, a film is formed on a surface of the wafer W.

### <Substrate Unloading Step: S12>

Subsequently, the boat 58 accommodating the wafers W on which the film is formed is unloaded from the process chamber 54.

According to the present embodiments, it is possible to obtain one or more effects described below.

(a) By providing the first gap G1 and the second gap G2, it is possible to reduce a dust generation caused by a movement of the bushing 430 in the up-down direction.

(b) By providing the first gap G1 and the second gap G2, a flow path length is increased and a conductance is reduced. As a result, it is possible to doubly suppress a gas leakage from the gas pipe 422 to a surrounding area thereof.

(c) Since the thickness of the packing 440 is reduced, the packing 440 is less likely to fall over when a lateral force is applied to the packing 440. As a result, it is possible to suppress a peeling of the packing 440 and a gas leakage due to such a peeling.

(d) By narrowing the gaps and increasing the number of the gaps, the conductance is reduced. Therefore, by providing the three gaps (that is, the first gap G1, the second gap G2 and the third gap G3), it is possible to further suppress the leakage. In other words, it is possible to triply suppress the gas leakage by the first gap G1, the second gap G2 and the third gap G3.

(e) Since the gas leakage is suppressed, it is possible to reduce an amount of the N₂ gas used as the purge gas. For example, while the amount the N₂ gas used when a gas leakage structure of (b) or (c) mentioned above is not provided is 18 SLM, the amount of the N₂ gas used in the present embodiments is between 8 SLM and 10 SLM.

(f) Since the bushing 430 slides against the gas pipe 422 rather than using the packing 440 or an O-ring whose friction is high, the bushing 430 is moved smoothly. Thereby, it is possible to improve contact characteristics with respect to the purge port 21.

(g) Since the purge nozzle 410 can be moved over a wide range while maintaining a pressing force by the spring 470, it is possible to adapt to various pods 20 with different heights of sealing surfaces on back surfaces of the pods 20.

The technique of the present disclosure is described in detail by way of the embodiments mentioned above. However, the technique of the present disclosure is not limited thereto. The technique of the present disclosure may be modified in various ways without departing from the scope thereof.

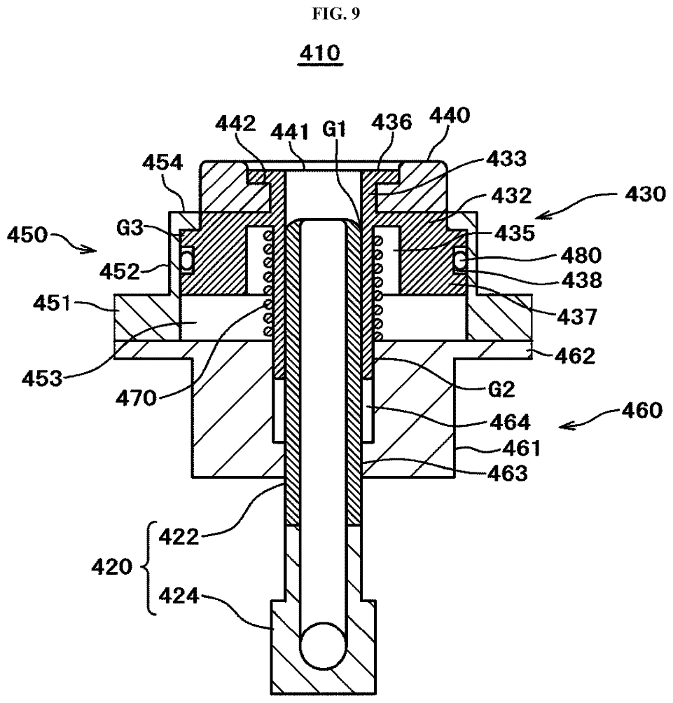

A configuration of a purge nozzle according to each modified example will be described with reference to FIGS. 9 to 11.

The purge nozzle according to the embodiments mentioned above is not provided with a sealing structure as a seal ring. As shown in FIG. 9, according to a first modified example, a seal ring (for example, an O-ring 480) is provided between a side surface of the flange 437 of the bushing 430 and an inner periphery of the cylinder 452 of the ring 450.

The O-ring 480 (which is located in a groove 438 provided in the flange 437 of the bushing 430) is compressed by the cylinder 452 of the ring 450 and the flange 437 of the bushing 430, and is in close contact with the cylinder 452 and the flange 437. In other words, the O-ring 480 seals a gap between the ring 450 and the bushing 430 at the through-hole 453. As a result, since the third gap G3 between the cylinder 452 and the flange 437 is sealed, it is possible to prevent the purge gas from leaking through the third gap G3. According to the present modified example, it is also possible to obtain substantially the same effects as in the embodiments mentioned above.

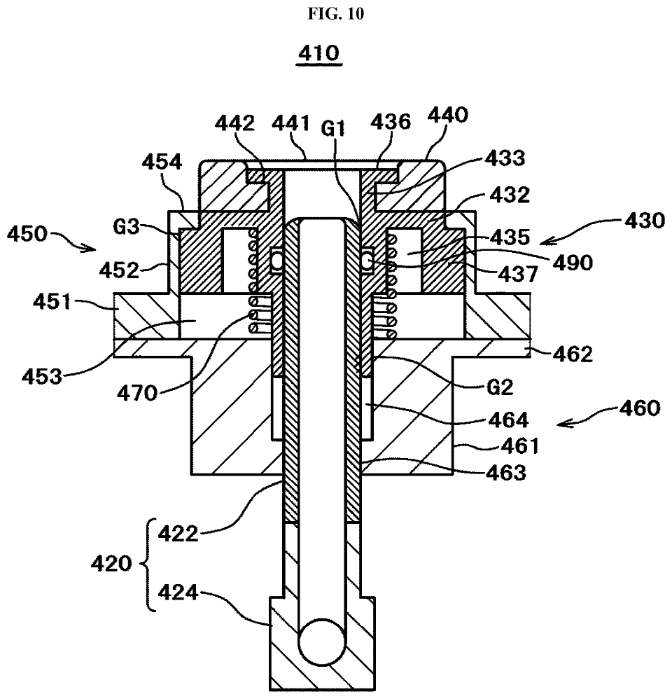

As shown in FIG. 10, according to a second modified example, a seal ring (for example, an O-ring 490) is provided between the cylinder 433 of the bushing 430 and the gas pipe 422.

The O-ring 490 (which is located in a groove 436a provided on the inner surface of the cylinder 433) is compressed by the gas pipe 422 and the cylinder 433, and is in close contact with the gas pipe 422 and the cylinder 433. In other words, the O-ring 490 seals a gap between the piping structure 420 and the bushing 430. As a result, since the first gap G1 between the gas pipe 422 and the cylinder 433 is sealed, it is possible to prevent the purge gas from leaking through the first gap G1. According to the present modified example, it is also possible to obtain substantially the same effects as in the embodiments mentioned above.

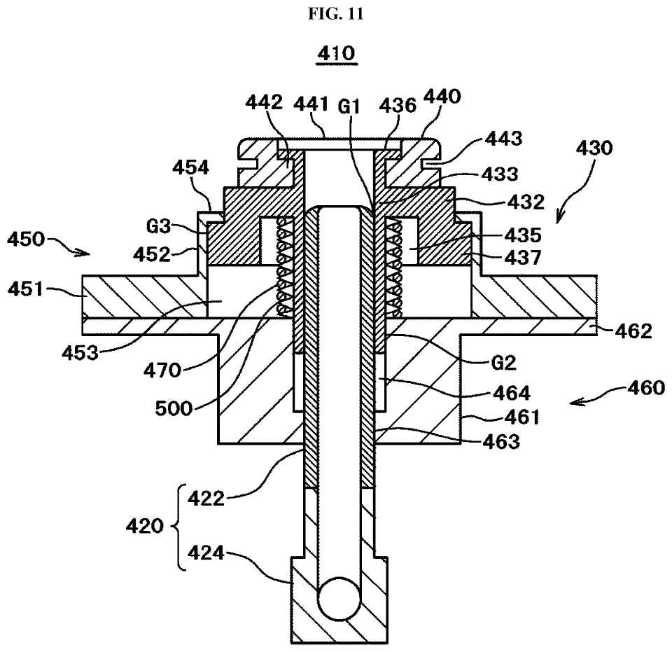

As shown in FIG. 11, according to a third modified example, a structure of the packing 440 is modified from that of the purge nozzle 410 of the embodiments mentioned above, and a bellows 500 is added to seal between the bushing 430 and the port flange 460. In addition, the spring 470 whose diameter is increased is located on an outer periphery of the bellows 500. The packing 440 is provided with a groove (thin-walled structure) 443. The groove 443 acts to adjust an elasticity applied to a surface (which abuts against the purge port 21) in a direction perpendicular to the surface such that the elasticity at a periphery of the surface is smaller than the elasticity at a central portion of the surface. As a result, it is possible to prevent the purge gas from leaking. According to the present modified example, it is also possible to obtain substantially the same effects as in the embodiments mentioned above.

The embodiments and the modified examples mentioned above may be appropriately combined. The process procedures and the process conditions of each combination thereof may be substantially the same as those of the embodiments mentioned above or the modified examples mentioned above.

For example, the embodiments mentioned above are described by way of an example in which a batch type substrate processing apparatus (vertical type apparatus) capable of simultaneously processing a plurality of substrates is used. However, the technique of the present disclosure is not limited thereto. For example, the technique of the present disclosure may be preferably applied to an apparatus such as a single wafer type apparatus provided with an IBR (Internal Buffer Rack), a multi wafer type apparatus and an apparatus capable of processing a substrate with a liquid such as a cleaning liquid.

According to some embodiments of the present disclosure, it is possible to improve the contact characteristics with respect to the purge nozzle.

What is claimed is:

1. A purge nozzle comprising:
a close contact structure provided with an opening in a center portion thereof and configured to be capable of coming into close contact with a purge port of a substrate container;
a bushing connected to a surface of the close contact structure opposite to a surface of the close contact structure in close contact with the purge port, and provided with a cylinder communicating with the opening;
a gas pipe clearance-fitted with an inner periphery of the cylinder along a first gap;
a port flange fixedly connected to the gas pipe and provided with a flange surface substantially perpendicular to a pipe axis of the gas pipe; and
an elastic structure provided between the port flange and the bushing and configured to bias the bushing in a direction away from the port flange,
wherein the port flange is provided with a hole concentric with the gas pipe, a diameter of the hole corresponds to an outer diameter of the cylinder, and an outer periphery of the cylinder is clearance-fitted with the hole along a second gap.

2. The purge nozzle of claim 1, wherein the close contact structure is of an annular shape, and a thickness of the close contact structure is set to be smaller than a difference between outer and inner diameters thereof.

3. The purge nozzle of claim 1, wherein a stepped structure is provided on a side surface of the opening of the close contact structure, the cylinder extends into the opening to form a flange at a front end of the cylinder, and the close contact structure is fixed by fitting the stepped structure into the flange.

4. The purge nozzle of claim 1, further comprising
a ring fixed to the flange surface and configured to restrict the bushing from moving away more than a predetermined distance from the port flange.

5. The purge nozzle of claim 4, wherein a side surface of the bushing is clearance-fitted with an inner peripheral surface of the ring along a third gap, and wherein a gas leakage is triply suppressed by the first gap, the second gap and the third gap.

6. The purge nozzle of claim 5, wherein the first gap is set to be larger than the second gap and the third gap.

7. The purge nozzle of claim 1, wherein one end of the gas pipe is within the cylinder and located at such a position as not to protrude from the bushing when the bushing is pressed in by an external force.

8. The purge nozzle of claim 1, wherein a sliding surface of the cylinder against the gas pipe is made of a resin, and is of a smooth cylindrical shape.

9. The purge nozzle of claim 1, wherein no seal ring is provided between the cylinder and the gas pipe.

10. The purge nozzle of claim 4, further comprising
a seal ring provided between the cylinder and the gas pipe or between a side surface of the bushing and an inner periphery of the ring.

11. The purge nozzle of claim 8, wherein a length of the sliding surface in a sliding direction is 1.5 times or more a diameter of the gas pipe.

12. The purge nozzle of claim 1, wherein the close contact structure is provided with a groove, and
wherein the groove acts to adjust an elasticity applied to a surface abutting against the purge port in a direction perpendicular to the surface such that the elasticity at a periphery of the surface abutting against the purge port is smaller than the elasticity at a central portion of the surface abutting against the purge port.

13. A substrate processing apparatus using the purge nozzle of claim 1, the substrate processing apparatus comprising:
a plurality of mounting plates on which the substrate container is capable of being placed; and
an integrated gas supply system connected to at least one of a plurality of purge nozzles and configured to supply a gas,
wherein the plurality of purge nozzles are provided for the plurality of mounting plates, respectively.

14. The substrate processing apparatus of claim 13, wherein the substrate container is capable of being placed on a mounting plate among the plurality of mounting plates by a wire-suspended type container transfer structure.

15. The substrate processing apparatus of claim 13, wherein a front end of the gas pipe does not protrude from a mounting plate among the plurality of mounting plates, and the close contact structure is further configured to be capable of being pressed to a position where the close contact structure does not protrude from the mounting plate.

16. The substrate processing apparatus of claim 13, further comprising
a controller configured to be capable of receiving, from a host apparatus, information on a type of the substrate container inserted to the substrate processing apparatus, and capable of controlling the integrated gas supply system to supply the gas through the purge port corresponding to the type of the substrate container placed on a mounting plate among the plurality of mounting plates.

17. A method of purging a substrate container in a substrate processing apparatus comprising:
a purge nozzle comprising:
a close contact structure provided with an opening in a center portion thereof and configured to be capable of coming into close contact with a purge port of the substrate container;
a bushing connected to a surface of the close contact structure opposite to a surface of the close contact structure in close contact with the purge port, and provided with a cylinder communicating with the opening;
a gas pipe clearance-fitted with an inner periphery of the cylinder, along a first gap;
a port flange fixedly connected to the gas pipe and provided with a flange surface substantially perpendicular to a pipe axis of the gas pipe; and
an elastic structure provided between the port flange and the bushing and configured to bias the bushing in a direction away from the port flange,
wherein the port flange is provided with a hole concentric with the gas pipe, a diameter of the hole corresponds to an outer diameter of the cylinder, and an outer periphery of the cylinder is clearance-fitted with the hole, along a second gap;
a plurality of mounting plates on which the substrate container is capable of being placed;
an integrated gas supply system configured to supply a gas to at least one of a plurality of purge nozzles, wherein the plurality of purge nozzles are provided for the plurality of mounting plates, respectively; and
a controller configured to be capable of receiving, from a host apparatus, information on a type of the substrate container inserted to the substrate processing apparatus, and capable of controlling the integrated gas supply system to supply the gas through the purge port corresponding to the type of the substrate container placed on a mounting plate among the plurality of mounting plates,
the method comprising:
(a) placing the substrate container on the mounting plate; and
(b) purging the substrate container through the purge nozzle.

18. A method of manufacturing a semiconductor device, comprising
the method of claim 17.

19. A non-transitory computer-readable recording medium storing a program that causes a substrate processing apparatus, by a computer, to perform:
(a) placing a substrate container on a mounting plate; and
(b) purging the substrate container through a purge nozzle,
wherein the substrate processing apparatus comprises:
the purge nozzle comprising:
a close contact structure provided with an opening in a center portion thereof and configured to be capable of forming a close contact with a purge port of the substrate container;
a bushing connected to a surface of the close contact structure opposite to a surface of the close contact structure in close contact with the purge port, and provided with a cylinder communicating with the opening;
a gas pipe clearance-fitted with an inner periphery of the cylinder, along a first gap;
a port flange fixedly connected to the gas pipe and provided with a flange surface substantially perpendicular to a pipe axis of the gas pipe; and
an elastic structure provided between the port flange and the bushing and configured to bias the bushing in a direction away from the port flange,
wherein the port flange is provided with a hole concentric with the gas pipe, a diameter of the hole is set to correspond to an outer diameter of the cylinder, and an outer periphery of the cylinder is clearance-fitted with the hole, along a second gap;
a plurality of mounting plates on which the substrate container is capable of being placed;
an integrated gas supply system configured to supply a gas to at least one of a plurality of purge nozzles, wherein the plurality of purge nozzles are provided for the plurality of mounting plates, respectively; and
a controller configured to be capable of receiving, from a host apparatus, information on a type of the substrate container inserted to the substrate processing apparatus, and capable of controlling the integrated gas supply system to supply the gas through the purge port corresponding to the type of the substrate container placed on the mounting plate among the plurality of mounting plates.
